(19) United States
(12) Patent Application Publication
(10) Pub. No.: US 2024/0380380 A1
(43) Pub. Date: Nov. 14, 2024

(54) RESONATOR, RESONANCE DEVICE, AND METHOD FOR MANUFACTURING RESONATOR

(71) Applicant: Murata Manufacturing Co., Ltd., Nagaokakyo-shi (JP)

(72) Inventor: Masakazu FUKUMITSU, Nagaokakyo-shi (JP)

(21) Appl. No.: 18/780,784

(22) Filed: Jul. 23, 2024

Related U.S. Application Data
(63) Continuation of application No. PCT/JP2022/033156, filed on Sep. 2, 2022.

(30) Foreign Application Priority Data
Feb. 28, 2022 (JP) 2022-029891

(51) Int. Cl. H03H 9/17; H03H 9/10

(52) U.S. Cl. CPC H03H 9/17; H03H 9/10

(57) ABSTRACT

A resonator that includes: a silicon substrate containing phosphorus; and a vibration portion on the silicon substrate and constructed to vibrate in a predetermined vibration mode as a main vibration. In the silicon substrate, a concentration of the phosphorus is 1.1×10²⁰ [atoms/cm³] or higher, and a concentration of carbon is 1.1×10¹⁸ [atoms/cm³] or lower.

### CROSS REFERENCE TO RELATED APPLICATIONS

The present application is a continuation of International application No. PCT/JP2022/033156, filed Sep. 2, 2022, which claims priority to Japanese Patent Application No. 2022-029891, filed Feb. 28, 2022, the entire contents of each of which are incorporated herein by reference.

### TECHNICAL FIELD

The present disclosure relates to a resonator, a resonance device, and a method for manufacturing a resonator.

### BACKGROUND ART

In the related art, a resonance device using a technology of micro electro mechanical systems (MEMS) is used as a timing device, for example. The resonance device is mounted on a printed circuit board incorporated in an electronic device such as a smartphone. The resonance device includes a lower substrate, an upper substrate forming a cavity between the lower substrate and the upper substrate, and a resonator disposed inside the cavity between the lower substrate and the upper substrate.

The resonator is generally manufactured from a semiconductor wafer such as a silicon (Si) wafer. For example, Patent Document 1 discloses a method for manufacturing a semiconductor wafer as follows. A diffusion source of N-type impurities of a wafer in a first diffusion step is used as phosphorus of phosphorus oxychloride. Vapor of the phosphorus oxychloride is continuously supplied together with an Ar gas containing 0.5% or more of O₂ gas. A temperature is maintained at 1,100° C. to 1, 300° C. to diffuse the phosphorus for a required time.
Patent Document 1: Japanese Unexamined Patent Application Publication No. H11-8201

### SUMMARY OF THE DISCLOSURE

The following method is known. A silicon substrate having a low electric resistivity (hereinafter, simply referred to as a “resistivity”) is used for a vibration portion of the resonator. In this manner, so-called frequency temperature characteristics are improved in which a change rate of a resonant frequency with respect to a temperature change is reduced with regard to the resonant frequency of the resonator.

In order to form the silicon substrate having the low resistivity, a method for doping impurities (dopants) such as the phosphorus (P) into a silicon wafer is known.

However, according to the method in the related art, there is a possibility that it is difficult to raise concentration of the impurities more than ever, or that lowering the resistivity is hindered due to the impurities inactivated by a contaminant such as carbon (C) remaining on a front surface of the silicon wafer.

The present disclosure is made in view of the above-described circumstances, and one of objects of the present disclosure is to provide a resonator, a resonance device, and a method for manufacturing a resonator which can lower a resistivity of a vibration portion, compared to the related art.

According to one aspect of the present disclosure, there is provided a resonator including: a silicon substrate containing phosphorus; and a vibration portion on the silicon substrate and constructed to vibrate in a predetermined vibration mode as a main vibration. In the silicon substrate, a concentration of the phosphorus is 1.1×10²⁰ [atoms/cm³] or higher, and a concentration of carbon is 1.1×10¹⁸ [atoms/cm³] or lower.

According to another aspect of the present disclosure, there is provided a resonator including: a silicon substrate containing phosphorus; and a vibration portion on the silicon substrate and constructed to vibrate in a predetermined vibration mode as a main vibration, the vibration portion being formed on a silicon substrate containing phosphorus. In the silicon substrate, a concentration of the phosphorus is equal to or more than 110 times a concentration of carbon.

According to still another aspect of the present disclosure, there is provided a resonator including: a silicon substrate containing phosphorus; and a vibration portion on the silicon substrate and constructed to vibrate in a predetermined vibration mode as a main vibration, the vibration portion being formed on a silicon substrate containing phosphorus. A resistivity of the silicon substrate is 0.60 [mΩ·cm] or lower.

According to one aspect of the present disclosure, there is provided a resonance device including a lid body, and the above-described resonator.

According to one aspect of the present disclosure, there is provided a method for manufacturing a resonator that includes: adding phosphorous to a silicon wafer; heating the silicon wafer in an oxygen atmosphere to form a silicon oxide film; removing the silicon oxide film from the silicon wafer; forming a silicon substrate by performing the forming of the silicon oxide film and the removing of the silicon oxide film once or more times; and forming a vibration portion that vibrates in a predetermined vibration mode as a main vibration, on the silicon substrate.

According to the present disclosure, the resistivity of the vibration portion can be lowered, compared to the related art.

### BRIEF DESCRIPTION OF THE DRAWINGS

FIG. 1 is a perspective view schematically showing an appearance of a resonance device according to a first embodiment.

FIG. 2 is an exploded perspective view schematically showing a structure of the resonance device shown in FIG. 1.

FIG. 3 is a plan view schematically showing a structure of a resonator shown in FIG. 2.

FIG. 4 is a cross-sectional view schematically showing a configuration of a cross section taken along line IV-IV of the resonance device shown in FIGS. 1 to 3.

FIG. 5 is a flowchart showing a method for manufacturing a resonator according to the first embodiment.

FIG. 6 is a conceptual diagram for describing an example of a step shown in FIG. 5.

FIG. 7 is a conceptual diagram for describing another example of a step Shown in FIG. 5.

FIG. 8 is a conceptual diagram for describing a step Shown in FIG. 5.

FIG. 9 is a conceptual diagram for describing a case where a step shown in FIG. 5 is not performed.

FIG. 10 is a conceptual diagram for describing a step shown in FIG. 5.

FIG. 11 is a conceptual diagram for describing a step shown in FIG. 5.

FIG. 12 is a conceptual diagram for describing a step shown in FIG. 5.

FIG. 13 is a graph showing concentrations of phosphorus (P) and carbon (C) in a silicon substrate in the first embodiment.

FIG. 14 is a graph showing a resistivity of the silicon substrate in the first embodiment and a silicon wafer shown in FIG. 6.

FIG. 15 is a table for comparing the silicon substrate in the first embodiment with the silicon wafer shown in FIG. 6.

FIG. 16 is a flowchart showing a method for manufacturing a resonator in a second embodiment.

FIG. 17 is a cross-sectional view for describing a step shown in FIG. 16.

FIG. 18 is a cross-sectional view for describing a step shown in FIG. 16.

FIG. 19 is a cross-sectional view for describing an example of a step shown in FIG. 16.

FIG. 20 is a cross-sectional view for describing another example of a step shown in FIG. 16.

### DESCRIPTION OF THE PREFERRED EMBODIMENTS

Hereinafter, embodiments of the present disclosure will be described. In the following description of the drawings, the same or similar components are denoted by the same or similar reference numerals. The drawings are examples, and a dimension and a shape of each portion are schematic. The technical scope of the present disclosure should not be interpreted as being limited to the embodiments.

### First Embodiment

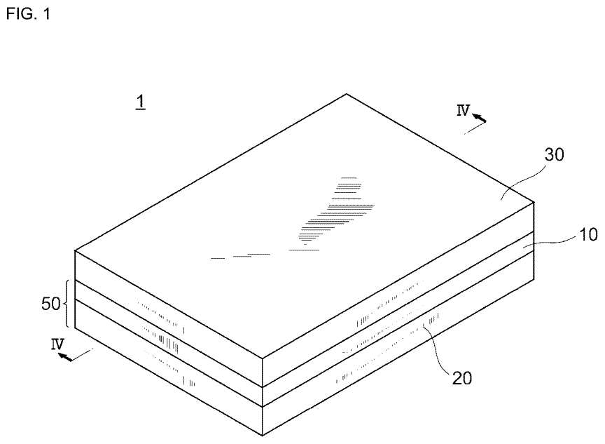

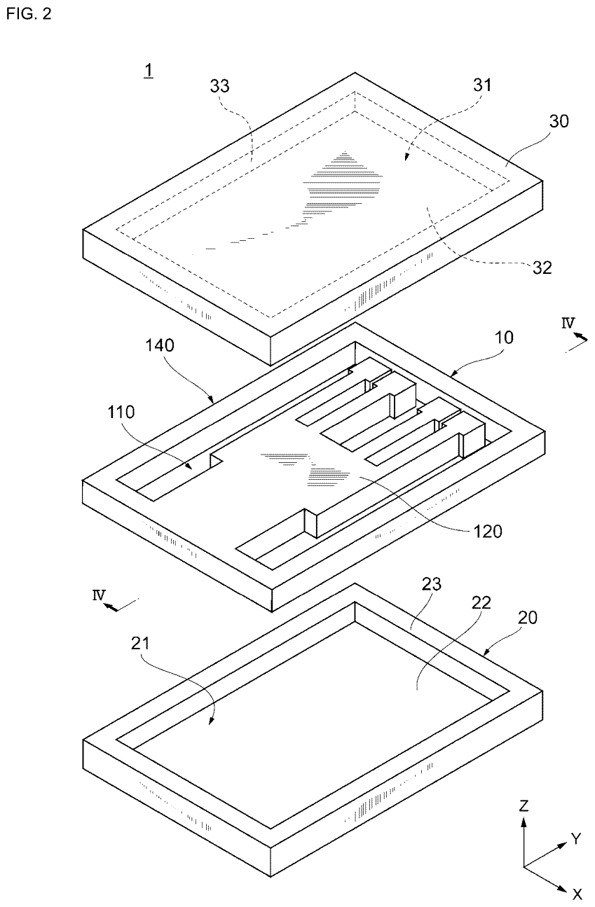

First, a schematic configuration of a resonance device according to a first embodiment of the present disclosure will be described with reference to FIGS. 1 and 2. FIG. 1 is a perspective view schematically showing an appearance of a resonance device 1 in the first embodiment. FIG. 2 is an exploded perspective view schematically showing a structure of the resonance device 1 shown in FIG. 1.

The resonance device 1 includes a lower lid 20, a resonator 10 (hereinafter, the lower lid 20 and the resonator 10 are collectively referred to as a “MEMS substrate 50”), and an upper lid 30. That is, the resonance device 1 is configured such that the MEMS substrate 50, a joint portion 60, and the upper lid 30 are laminated in this order. The upper lid 30 corresponds to an example of a “lid body” of the present disclosure.

Hereinafter, each configuration of the resonance device 1 will be described. In the following description, in the resonance device 1, a side on which the upper lid 30 is provided will be referred to as an upper side (or a front surface), and a side on which the lower lid 20 is provided will be referred to as a lower side (or a rear surface).

The resonator 10 is a MEMS oscillator manufactured by using a technology of MEMS. The resonator 10, the lower lid 20, and the upper lid 30 are joined such that the resonator 10 is sealed and a vibration space of the resonator 10 is formed. In addition, each of the resonator 10, the lower lid 20, and the upper lid 30 is formed of a silicon (Si) substrate (hereinafter, referred to as a “Si substrate”), and the Si substrates are joined to each other. In addition, each of the resonator 10, the lower lid 20, and the upper lid 30 may be formed of a silicon on insulator (SOI) substrate in which a silicon layer and a silicon oxide film are laminated. In particular, the resonator 10 and the lower lid 20 may be integrally formed by using a cavity SOI (CSOI) substrate.

The upper lid 30 includes a rectangular flat plate-shaped bottom plate 32 provided along an XY-plane and a side wall 33 extending from a peripheral edge portion of the bottom plate 32 in a Z-axis direction. The upper lid 30 has a recessed portion 31 defined by a front surface of the bottom plate 32 and an inner surface of the side wall 33 on a surface facing the resonator 10. The recessed portion 31 forms at least a portion of a vibration space which is a space in which the resonator 10 vibrates. In addition, a getter layer 34 (to be described later) is formed on a surface of the recessed portion 31 of the upper lid 30 on the side of the resonator 10. The upper lid 30 may have a flat plate-shaped configuration without having the recessed portion 31.

The lower lid 20 has a rectangular flat plate-shaped bottom plate 22 provided along the XY-plane and a side wall 23 extending from a peripheral edge portion of the bottom plate 22 in the Z-axis direction, that is, a lamination direction of the lower lid 20 and the resonator 10. The lower lid 20 has a recessed portion 21 formed by a front surface of the bottom plate 22 and an inner surface of the side wall 23 on a surface facing the resonator 10. The recessed portion 21 forms at least a portion of the vibration space of the resonator 10. The lower lid 20 may have a flat plate-shaped configuration without having the recessed portion 21. In addition, a getter layer may be formed on a surface of the recessed portion 21 of the lower lid 20 on the side of the resonator 10.

The vibration space of the resonator 10 is sealed in an airtight manner by joining the upper lid 30, the resonator 10, and the lower lid 20, and a vacuum state is maintained. For example, the vibration space may be filled with a gas such as an inert gas.

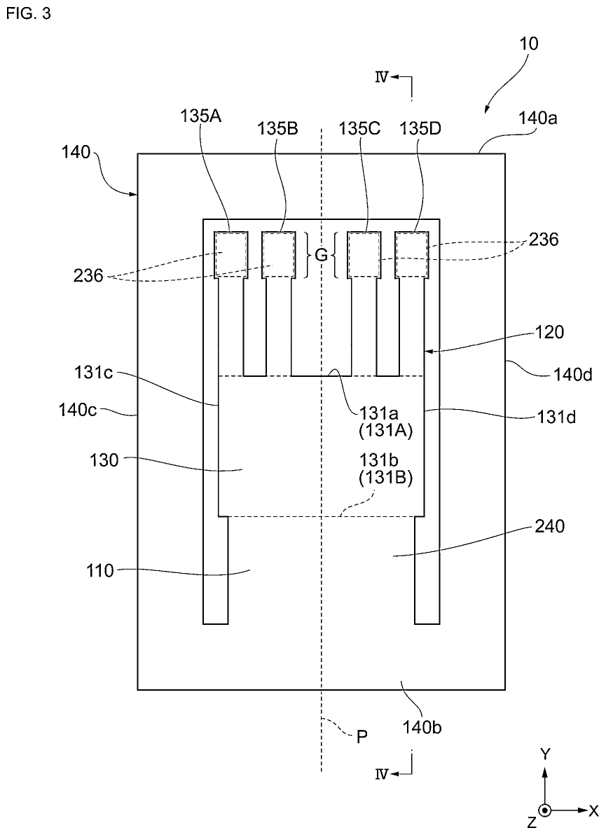

Next, a schematic configuration of the resonator included in the resonance device according to the first embodiment of the present disclosure will be described with reference to FIG. 3. FIG. 3 is a plan view schematically showing a structure of the resonator 10 shown in FIG. 2.

As shown in FIG. 3, the resonator 10 is a MEMS oscillator manufactured by using a technology of MEMS, and performs out-of-plane vibration in the XY-plane in a Cartesian coordinate system in FIG. 3. The resonator 10 is not limited to the resonator using an out-of-plane bending vibration mode, and may be configured to vibrate in a predetermined vibration mode as a main vibration (hereinafter, also referred to as a “main mode”). As the resonator of the resonance device 1, for example, a spread vibration mode, a thickness longitudinal vibration mode, a Lamb wave vibration mode, an in-plane bending vibration mode, or a surface acoustic wave vibration mode may be used. For example, the oscillators are applied to a timing device, an RF filter, a duplexer, an ultrasound resonator, an angular velocity sensor (gyro sensor), an acceleration sensor, and the like. In addition, the oscillators may be used for a piezoelectric mirror having an actuator function, a piezoelectric gyro, a piezoelectric microphone having a pressure sensor function, an ultrasonic vibration sensor, and the like. Furthermore, the oscillators may be applied to an electrostatic MEMS element, an electromagnetic drive MEMS element, and a piezoresistance MEMS element.

The resonator 10 includes a vibration portion 120, a holding portion 140, and a support arm 110.

The holding portion 140 is formed in a rectangular frame shape to surround an outer side portion of the vibration portion 120 along the XY-plane. For example, the holding portion 140 is integrally formed of a prism-shaped frame body. The holding portion 140 may be provided in at least a portion on the periphery of the vibration portion 120, and is not limited to a frame shape.

The support arm 110 is provided inside the holding portion 140, and connects the vibration portion 120 and the holding portion 140.

The vibration portion 120 is provided inside the holding portion 140, and a space is formed at a predetermined interval between the vibration portion 120 and the holding portion 140. In an example shown in FIG. 3, the vibration portion 120 has a base portion 130 and four vibration arms 135A to 135D (hereinafter, collectively referred to as a “vibration arm 135”). The number of the vibration arms is not limited to four, and is set to any number of one or more, for example. In the present embodiment, each of the vibration arms 135A to 135D and the base portion 130 are integrally formed.

In a plan view, the base portion 130 has long sides 131a and 131b in an X-axis direction and short sides 131c and 131d in a Y-axis direction. The long side 131a is one side of a surface (hereinafter, also referred to as a “front end 131A”) of a front end of the base portion 130, and the long side 131b is one side of a surface (hereinafter, also referred to as a “rear end 131B”) of a rear end of the base portion 130. In the base portion 130, the front end 131A and the rear end 131B are provided to face each other.

The base portion 130 is connected to the vibration arm 135 in the front end 131A, and is connected to the support arm 110 (to be described later) in the rear end 131B. The base portion 130 has a substantially rectangular shape in a plan view in the example shown in FIG. 3, but is not limited thereto. The base portion 130 may be formed in a substantially plane symmetry manner with respect to a virtual plane P which is defined along a vertical bisector line of the long side 131a. For example, the base portion 130 may have a trapezoidal shape in which the long side 131b is shorter than the long side 131a, or may have a semicircular shape in which the long side 131a is set as a diameter. In addition, each surface of the base portion 130 is not limited to a flat surface, and may be a curved surface. The virtual plane P is a plane that passes through a center in an alignment direction of the vibration arms 135 in the vibration portion 120.

In the base portion 130, a base portion length which is a longest distance between the front end 131A and the rear end 131B in a direction from the front end 131A toward the rear end 131B is approximately 35 μm. In addition, a base portion width which is a longest distance between side ends of the base portion 130 in a width direction orthogonal to a direction of the base portion length is approximately 265 μm.

The vibration arms 135 each extend in the Y-axis direction, and have the same size. The vibration arms 135 each are provided in parallel in the Y-axis direction between the base portion 130 and the holding portion 140. One end is connected to the front end 131A of the base portion 130 to be a fixed end, and the other end is an open end. In addition, the vibration arms 135 each are aligned in parallel at a predetermined interval in the X-axis direction. In the vibration arm 135, for example, a width in the X-axis direction is approximately 50 μm, and a length in the Y-axis direction is approximately 465 μm.

In each of the vibration arms 135, for example, a portion of approximately 150 μm from the open end is wider in the X-axis direction than other portions of the vibration arm 135. The wider portion will be referred to as a weight portion G. For example, in the weight portion G, a lateral width along the X-axis direction is wider by 10 μm than other portions of the vibration arm 135, and a width along the X-axis direction is approximately 70 μm. The weight portion G is integrally formed with the vibration arm 135 through the same process. When the weight portion G is formed, in the vibration arm 135, a weight per unit length on the open end side is heavier than that on the fixed end side. Accordingly, each of the vibration arms 135 has the weight portion G on the open end side. In this manner, an amplitude of the vibration in an up-down direction of each vibration arm can be increased.

A protection film 235 (to be described later) is formed on a front surface (surface facing the upper lid 30) of the vibration portion 120 to cover an entire surface thereof. In addition, a frequency adjustment film 236 is formed on each front surface of the protection film 235 in a tip on the open end side of the vibration arms 135A to 135D. A resonant frequency of the vibration portion 120 can be adjusted by the protection film 235 and the frequency adjustment film 236.

In the present embodiment, the substantially entire surface of the front surface (surface facing the upper lid 30) of the resonator 10 is covered with the protection film 235. Furthermore, the substantially entire surface of the front surface of the protection film 235 is covered with a parasitic capacitance reduction film 240. However, the protection film 235 may cover at least the vibration arm 135, and is not limited to the configuration in which the substantially entire surface of the resonator 10 is covered.

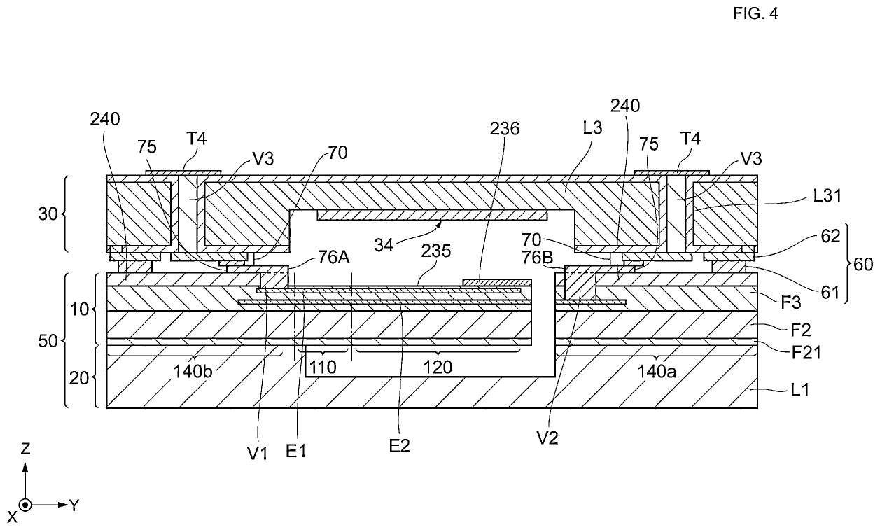

Next, a multilayer structure of the resonance device 1 according to the first embodiment of the present disclosure will be described with reference to FIG. 4. FIG. 4 is a cross-sectional view schematically showing a configuration of a cross section taken along line IV-IV of the resonance device 1 shown in FIGS. 1 to 3.

As shown in FIG. 4, in the resonance device 1, the holding portion 140 of the resonator 10 is joined onto the side wall 23 of the lower lid 20, and the holding portion 140 of the resonator 10 and the side wall 33 of the upper lid 30 are further joined to each other. In this way, the resonator 10 is held between the lower lid 20 and the upper lid 30, and the vibration space in which the vibration portion 120 vibrates is formed by the lower lid 20, the upper lid 30, and the holding portion 140 of the resonator 10. In addition, a terminal T4 is formed on an upper surface (surface opposite to the surface facing the resonator 10) of the upper lid 30. The terminal T4 and the resonator 10 are electrically connected by a through electrode V3, a connection wire 70, and contact electrodes 76A and 76B.

The upper lid 30 is formed of a Si substrate L3 having a predetermined thickness. The upper lid 30 is joined to the holding portion 140 of the resonator 10 by the joint portion 60 (to be described later) in a peripheral portion thereof (side wall 33). A front surface facing the resonator 10 in the upper lid 30 is covered with a silicon oxide film L31. For example, the silicon oxide film L31 is silicon dioxide (SiO₂), and is formed on the front surface of the Si substrate L3 by oxidation of the front surface of the Si substrate L3 or chemical vapor deposition (CVD). It is preferable that the rear surface of the upper lid 30 and the side surface of the through electrode V3 are covered with the silicon oxide film L31.

In addition, the getter layer 34 is formed on a surface on a side facing the resonator 10 in the recessed portion 31 of the upper lid 30. For example, the getter layer 34 is formed of titanium (Ti) or the like, and suctions an outgas generated in the vibration space. In the upper lid 30 according to the present embodiment, the getter layer 34 is formed on substantially the entire surface facing the resonator 10 in the recessed portion 31. Therefore, it is possible to suppress a decrease in a vacuum degree of the vibration space.

In addition, the through electrode V3 of the upper lid 30 is formed by filling a through-hole formed in the upper lid 30 with a conductive material. For example, the conductive material for filling is polycrystalline silicon (Poly-Si) doped with impurities, copper (Cu), gold (Au), single crystal silicon doped with impurities, and the like. The through electrode V3 functions as a wire that electrically connects the terminal T4 and the connection wire 70.

The bottom plate 22 and the side wall 23 of the lower lid 20 are integrally formed of the Si wafer L1. In addition, the lower lid 20 is joined to the holding portion 140 of the resonator 10 by an upper surface of the side wall 23. For example, the thickness of the lower lid 20 defined in the Z-axis direction is 150 μm, and for example, a depth of the recessed portion 21 is 50 μm. The Si wafer L1 is formed of silicon which is not degenerated, and the resistivity thereof is 16 mΩ·cm or higher, for example.

The vibration portion 120, the holding portion 140, and the support arm 110 in the resonator 10 are integrally formed in the same process. In the resonator 10, a piezoelectric thin film F3 is formed on a Si substrate F2 to cover the Si substrate F2, and a metal layer E2 is laminated on the piezoelectric thin film F3. The piezoelectric thin film F3 is laminated on the metal layer E2 to cover the metal layer E2, and a metal layer E1 is laminated on the piezoelectric thin film F3. The protection film 235 is laminated on the metal layer E1 to cover the metal layer E1, and the parasitic capacitance reduction film 240 is laminated on the protection film 235. Each outer shape of the holding portion 140, the base portion 130, the vibration arm 135, and the support arm 110 is formed in such a manner that a multilayer body formed of the Si substrate F2, the piezoelectric thin film F3, the metal layer E2, the metal layer E1, the protection film 235, and the like is removed by dry etching with argon (Ar) ion beam irradiation, for example, and is patterned.

For example, the Si substrate F2 may be formed of a degenerated n-type silicon (Si) semiconductor having the thickness of approximately 6 μm. The degenerated silicon (Si) contains phosphorus (P) as an n-type dopant. In the present embodiment, the Si substrate F2 is an example of a silicon substrate (to be described later), and details thereof will be described later.

Since the Si substrate F2 is the degenerated silicon (Si), for example, a degenerated silicon substrate having a low resistance value is used. In this manner, the Si substrate F2 itself can function as a lower electrode of the resonator 10. In this case, the above-described metal layer E2 is omitted.

For example, the silicon oxide layer F21 which is silicon dioxide (SiO₂) is formed on a lower surface of the Si substrate F2, as an example of a temperature characteristics correction layer. In this manner, temperature characteristics can be improved. The silicon oxide layer F21 may be formed on the upper surface of the Si substrate F2, or may be formed on both the upper surface and the lower surface of the Si substrate F2.

In addition, for example, the metal layers E1 and E2 have the thickness of approximately 0.1 μm or larger and 0.2 μm or smaller, and are patterned into a desired shape by etching or the like after film formation. As the metal layers E1 and E2, metal having a crystal structure of a body-centered cubic structure is used. Specifically, the metal layers E1 and E2 are formed of molybdenum (Mo), tungsten (W), or the like.

For example, the metal layer E1 is formed on the vibration portion 120 to function as an upper electrode. In addition, the metal layer E1 is formed on the support arm 110 and the holding portion 140 to function as a wire for connecting the upper electrode to an AC power source provided outside the resonator 10.

On the other hand, the metal layer E2 is formed on the vibration portion 120 to function as the lower electrode. In addition, the metal layer E2 is formed on the support arm 110 and the holding portion 140 to function as a wire for connecting the lower electrode to a circuit provided outside the resonator 10.

The piezoelectric thin film F3 is a thin film of a piezoelectric body that converts an applied voltage into vibration. The piezoelectric thin film F3 is formed of a material whose crystal structure is a wurtzite-type hexagonal structure, and for example, can have nitride or oxide such as aluminum nitride (AlN), scandium aluminum nitride (ScAlN), zinc oxide (ZnO), gallium nitride (GaN), or indium nitride (InN) as a main component. The scandium aluminum nitride is obtained by substituting a portion of aluminum in aluminum nitride with scandium, and may be substituted with two elements such as magnesium (Mg) and niobium (Nb), or magnesium (Mg) and zirconium (Zr), instead of scandium. In addition, for example, the piezoelectric thin film F3 has the thickness of 1 μm, but the thickness of approximately 0.2 μm to 2 μm can also be used.

The piezoelectric thin film F3 stretches and contracts in an in-plane direction of the XY-plane, that is, the Y-axis direction, in response to an electric field applied to the piezoelectric thin film F3 by the metal layers E1 and E2. Since the piezoelectric thin film F3 stretches and contracts, the free end of the vibration arm 135 is displaced toward inner surfaces of the lower lid 20 and the upper lid 30, and vibrates in the out-of-plane bending vibration mode.

In the present embodiment, a phase of the electric field applied to the outer vibration arms 135A and 135D and a phase of the electric field applied to the inner vibration arms 135B and 135C are set to be mutually opposite phases. In this manner, the outer vibration arms 135A and 135D and the inner vibration arms 135B and 135C are displaced in mutually opposite directions. For example, when the free ends of the outer vibration arms 135A and 135D are displaced toward the inner surface of the upper lid 30, the free ends of the inner vibration arms 135B and 135C are displaced toward the inner surface of the lower lid 20.

The protection film 235 prevents oxidation of the metal layer E2 which is the upper electrode for piezoelectric vibration. It is preferable that the protection film 235 is formed of a material whose mass reduction speed through etching is slower than that of the frequency adjustment film 236. The mass reduction speed is represented by an etching speed, that is, a product of the thickness and density which are removed per unit time. For example, the protection film 235 is formed of an insulation film such as silicon nitride (SiN), silicon dioxide (SiO₂), or aluminum oxide (Al₂O₃), in addition to a piezoelectric film such as aluminum nitride (AlN), scandium aluminum nitride (ScAlN), zinc oxide (ZnO), gallium nitride (GaN), and indium nitride (InN). The thickness of the protection film 235 is approximately 0.2 μm, for example.

The frequency adjustment film 236 is formed on substantially the entire surface of the vibration portion 120, and thereafter, is formed only in a predetermined region by processing such as etching. The frequency adjustment film 236 is formed of a material whose mass reduction speed through etching is faster than that of the protection film 235. Specifically, the frequency adjustment film 236 is formed of metal such as molybdenum (Mo), tungsten (W), gold (Au), platinum (Pt), nickel (Ni), and titanium (Ti).

In addition, any magnitude relationship of the etching speed between the protection film 235 and the frequency adjustment film 236 is adopted as long as a relationship of the mass reduction speed therebetween is as described above.

The parasitic capacitance reduction film 240 is formed of tetraethyl orthosilicate (TEOS). The thickness of the parasitic capacitance reduction film 240 is approximately 1 μm. The parasitic capacitance reduction film 240 has a function of reducing parasitic capacitance in a lead wire portion, a function as an insulation layer when wires having different potentials cross each other, and a function as a standoff for widening the vibration space.

The connection wire 70 is electrically connected to the terminal T4 with the through electrode V3 interposed therebetween, and is electrically connected to the contact electrodes 76A and 76B.

The contact electrode 76A is formed to be in contact with the metal layer E1 of the resonator 10, and electrically connects the connection wire 70 and the resonator 10. The contact electrode 76B is formed to be in contact with the metal layer E2 of the resonator 10, and electrically connects the connection wire 70 and the resonator 10. Specifically, when the contact electrode 76A and the metal layer E1 are connected, a portion of the piezoelectric thin film F3, the protection film 235, and the parasitic capacitance reduction film 240 which are laminated on the metal layer E1 is removed to expose the metal layer E1, thereby forming a via V1. The inner side portion of the formed via V1 is filled with the same material as that of the contact electrode 76A, and the metal layer E1 and the contact electrode 76A are connected. Similarly, when the contact electrode 76B and the metal layer E2 are connected, a portion of the piezoelectric thin film F3 and the parasitic capacitance reduction film 240 which are laminated on the metal layer E2 is removed to expose the metal layer E2, thereby forming a via V2.

The inner side portion of the formed via V2 is filled with the contact electrode 76B, and the metal layer E2 and the contact electrode 76B are connected. For example, the contact electrodes 76A and 76B are formed of metal such as aluminum (Al), gold (Au), and tin (Sn). It is preferable that a connection location between the metal layer E1 and the contact electrode 76A and a connection location between the metal layer E2 and the contact electrode 76B are located in a region outside the vibration portion 120, and are connected by the holding portion 140 in the present embodiment.

The joint portion 60 is formed in a rectangular annular shape along the XY-plane on the periphery of the vibration portion 120 in the resonator 10, for example, between the MEMS substrate 50 (resonator 10 and lower lid 20) and the upper lid 30, on the holding portion 140. The joint portion 60 joins the MEMS substrate 50 and the upper lid 30 to seal the vibration space of the resonator 10. In this manner, the vibration space is sealed in an airtight manner, and the vacuum state is maintained.

In the present embodiment, the joint portion 60 includes an aluminum (Al) layer 61 formed on the MEMS substrate 50 and a germanium (Ge) layer 62 formed on the upper lid 30, and the MEMS substrate 50 and the upper lid 30 are joined by performing eutectic joining on the aluminum (Al) layer 61 and the germanium (Ge) layer 62.

In an example shown in FIG. 4, each of the aluminum (Al) layer 61 and the germanium (Ge) layer 62 is described as an independent layer, but actually, each interface is subjected to eutectic joining. The joint portion 60 may be formed of a gold (Au) film, a tin (Sn) film, or the like, or may be formed of a combination of gold (Au) and silicon (Si), gold (Au) and gold (Au), copper (Cu) and tin (Sn), or the like. In addition, in order to improve close contact, in the joint portion 60, titanium (Ti), titanium nitride (TiN), tantalum nitride (TaN), or the like may be thinly pinched between the laminated layers.

In the present embodiment, a configuration in which the joint portion 60 is provided on the entire periphery of the vibration portion 120 in the resonator 10 to seal the vibration space of the resonator 10 has been described as an example, but the present disclosure is not limited thereto. As long as the joint portion 60 joins the MEMS substrate 50 and the upper lid 30, for example, the joint portion 60 may be formed in a portion on the periphery of the vibration portion 120 in the resonator 10.

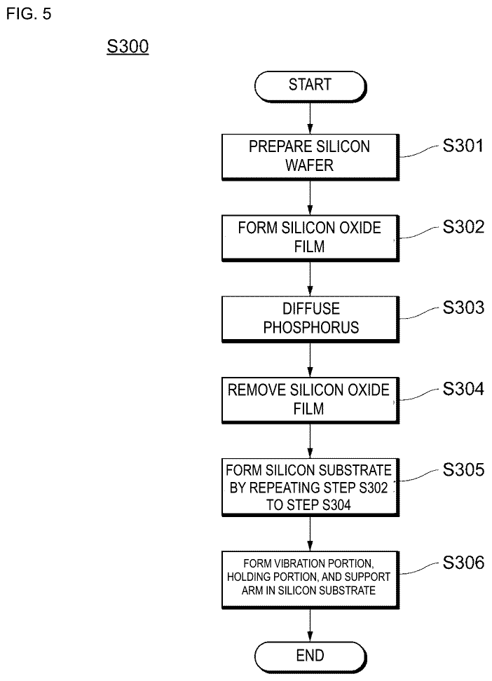

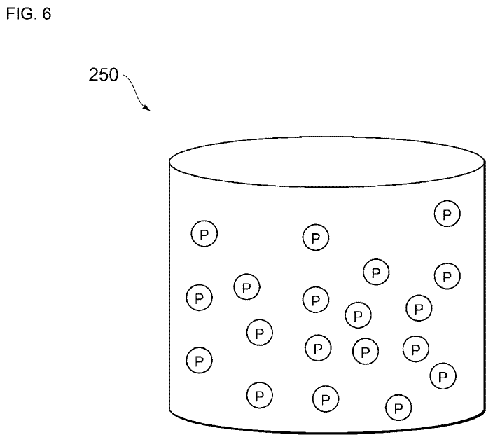

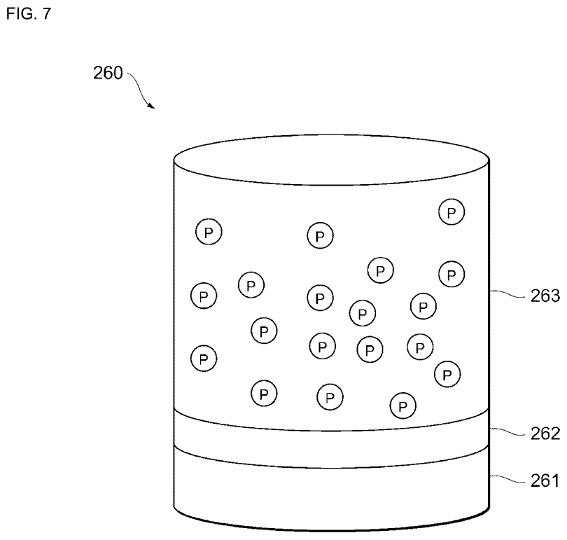

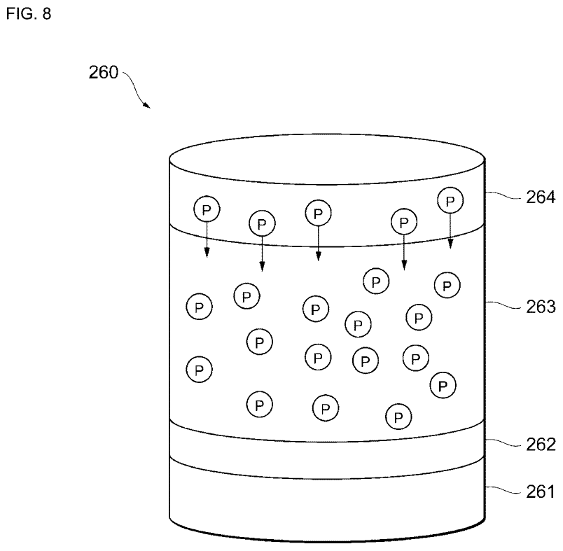

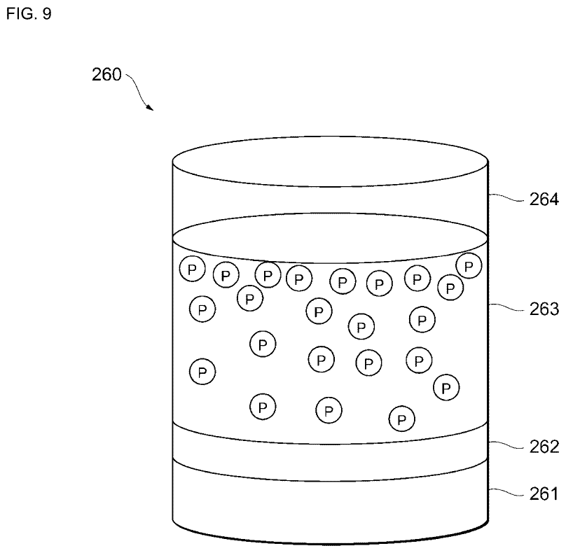

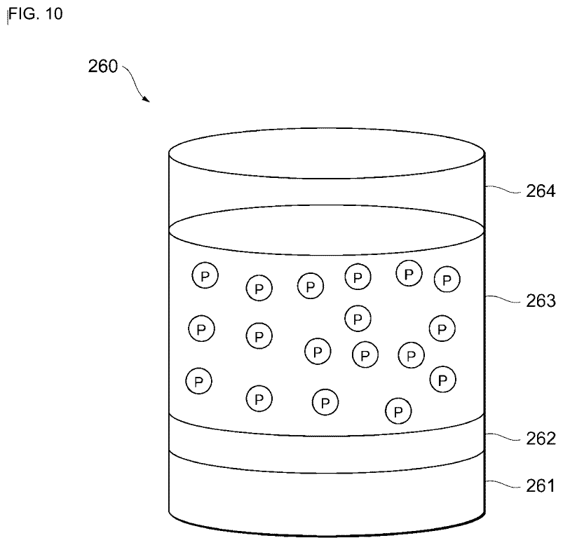

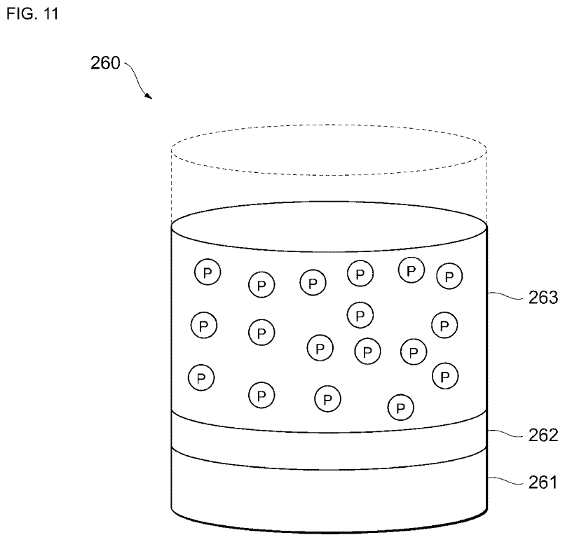

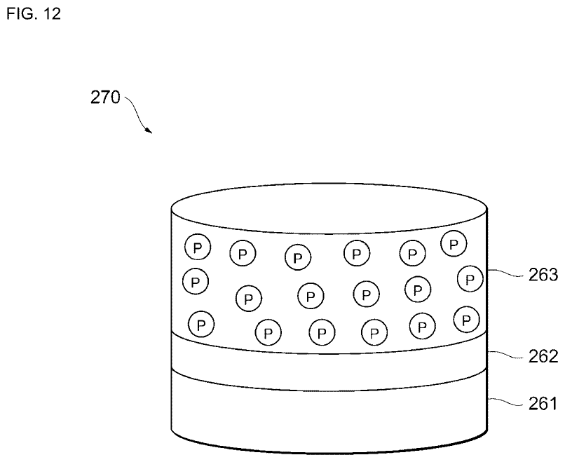

Next, a method for manufacturing the resonator according to the first embodiment of the present disclosure will be described with reference to FIGS. 5 to 12. FIG. 5 is a flowchart showing a method for manufacturing the resonator 10 in the first embodiment. FIG. 6 is a conceptual diagram for describing an example of Step S301 shown in FIG. 5. FIG. 7 is a conceptual diagram for describing another example of Step S301 shown in FIG. 5. FIG. 8 is a conceptual diagram for describing Step S302 shown in FIG. 5. FIG. 9 is a conceptual diagram for describing a case where Step S303 shown in FIG. 5 is not performed. FIG. 10 is a conceptual diagram for describing Step S303 shown in FIG. 5. FIG. 11 is a conceptual diagram for describing Step S304 shown in FIG. 5. FIG. 12 is a conceptual diagram for describing Step S305 shown in FIG. 5.

As shown in FIG. 5, first, a silicon wafer 250 is prepared (S301). Specifically, as shown in FIG. 6, the silicon wafer 250 to which phosphorus (P) is added is prepared. The silicon wafer 250 is obtained as follows. Crystal growth is performed on the basis of single crystal silicon (Si). An ingot is manufactured by doping phosphorus (P) as impurities, and the ingot is sliced to have a predetermined thickness. The thickness of the silicon wafer 250 is approximately 500 μm, for example.

In Step S301, a SOI wafer 260 manufactured by processing the silicon wafer 250 shown in FIG. 6 may be prepared. As shown in FIG. 7, the SOI wafer 260 includes a support layer 261, an insulation layer 262, and a silicon active layer 263.

The support layer 261 supports the silicon active layer 263 and the insulation layer 262 to facilitate handling of the silicon active layer 263. The support layer 261 is formed of single crystal silicon (Si), and has a thickness of approximately 500 μm, for example. The insulation layer 262 electrically insulates the silicon active layer 263. The insulation layer 262 is formed of silicon dioxide (SiO₂), and has the thickness of approximately 1 μm to 20 μm. The silicon active layer 263 is the silicon wafer 250 described above, and phosphorus (P) is added thereto. The thickness of the silicon active layer 263 is approximately 10 μm to 50 μm, for example. Since the silicon active layer 263 is supported by the support layer 261, the handling is facilitated even when the silicon active layer 263 is formed to be thinner than the silicon wafer 250.

Hereinafter, an example of preparing the SOI wafer 260 including the silicon active layer 263 which is the silicon wafer 250 will be described, unless otherwise specified.

Returning to FIG. 5, next, the SOI wafer 260 is heated in an oxygen atmosphere to form a silicon oxide film (SiO₂ film) 264 (S302).

Specifically, as shown in FIG. 8, in the SOI wafer 260, the front surface of the silicon active layer 263 is oxidized through thermal oxidation performed by heating in an oxygen atmosphere, and is changed to the silicon oxide film (SiO₂ film) 264 which is silicon dioxide. In the thermal oxidation, a heating temperature is approximately 1,100° C., and a heating time is approximately three hours. The thickness of the formed silicon oxide film (SiO₂ film) 264 is approximately 1 μm to 2 μm.

Here, when a portion of the silicon active layer 263 is changed to the silicon oxide film (SiO₂ film) 264 through the thermal oxidation, the silicon (Si) in the silicon active layer 263 is consumed as the silicon dioxide (SiO₂). Actually, in the formed silicon oxide film (SiO₂ film) 264, 45 vol % is silicon (Si). On the other hand, since phosphorus (P) has a property that phosphorus (P) is less likely to be solved in the silicon dioxide (SiO₂), the phosphorus (P) added to the silicon active layer 263 is accumulated inside the silicon active layer 263. As a result, concentration of the phosphorus (P) in the silicon active layer 263 can be raised, compared to concentration before the silicon oxide film (SiO₂ film) 264 is formed.

In addition, the silicon active layer 263 can be formed to be thinner than the silicon wafer 250. Therefore, the SOI wafer 260 can easily increase the concentration of the phosphorus (P), compared to the silicon wafer 250.

Returning to FIG. 5, next, the SOI wafer 260 after the thermal oxidation is further heated to diffuse phosphorus (P) (S303). More specifically, the SOI wafer 260 on which the silicon oxide film (SiO₂ film) 264 is formed is subjected to a heat treatment of heating at a high temperature for a long time in a nitrogen gas (N₂ gas) atmosphere, and the phosphorus (P) is diffused into the silicon active layer 263. This method is also called heat diffusion or drive-in. In the heat treatment, the heating temperature is approximately 1, 100° C., and the heating time is approximately seven hours to ten hours.

Here, when the heat treatment in Step S303 is not performed, as shown in FIG. 9, a bias may occur in a distribution of the phosphorus (P) in the silicon active layer 263, and the phosphorus (P) may be segregated in an interface or in the vicinity of the interface, which is a boundary between the silicon active layer 263 and the silicon oxide film (SiO₂ film) 264.

Therefore, in Step S303, the SOI wafer 260 is heated to diffuse the phosphorus (P). In this manner, as shown in FIG. 10, the phosphorus (P) in the silicon active layer 263 can be uniformly or substantially uniformly distributed.

In addition, Step S303 is not limited to a case of being performed separately from Step S302. For example, the phosphorus (P) may be diffused as a portion in Step S302, or may be diffused as a portion of the thermal oxidation in Step S302.

Returning to FIG. 5, next, the silicon oxide film (SiO₂ film) 264 formed in Step S302 is removed (S304).

Specifically, as shown in FIG. 11, the silicon oxide film (SiO₂ film) 264 is removed from the SOI wafer 260 through wet etching. As a result, the thickness of the silicon active layer 263 can be reduced by the thickness of the silicon oxide film (SiO₂ film) 264.

Returning to FIG. 5, next, Step S302 to Step S304 are repeated for the SOI wafer 260 to form a silicon substrate 270 (S305). As shown in FIG. 12, the silicon substrate 270 to be formed includes the support layer 261, the insulation layer 262, and the silicon active layer 263, as in the SOI wafer 260. The silicon substrate 270 is different from the SOI wafer 260 in that the thickness of the silicon active layer 263 is small and thin. As a result, the concentration of the phosphorus (P) in the silicon active layer 263 is increased. Details of the silicon active layer 263 in the silicon substrate 270 will be described later.

In the silicon substrate 270 formed in Step S305, the silicon active layer 263 corresponds to the Si substrate F2 shown in FIG. 4, the insulation layer 262 corresponds to the silicon oxide layer F21 shown in FIG. 4, and the support layer 261 corresponds to the Si wafer L1 of the lower lid 20 shown in FIG. 4.

Step S302 to Step S305 are repeated until the silicon substrate 270 reaches desired phosphorus (P) concentration and resistivity. Specifically, the number of times of repetition may be at least once or more, and is preferably twice or more.

Next, the vibration portion 120, the holding portion 140, and the support arm 110 are formed in the silicon substrate 270 formed in Step S305 (S306). As described above, the vibration portion 120, the holding portion 140, and the support arm 110 are integrally formed in the same process. In addition, in Step S305, the contact electrodes 76A and 76B and the aluminum (Al) layer 61 shown in FIG. 4 may be formed together. In this manner, the resonator 10 is manufactured.

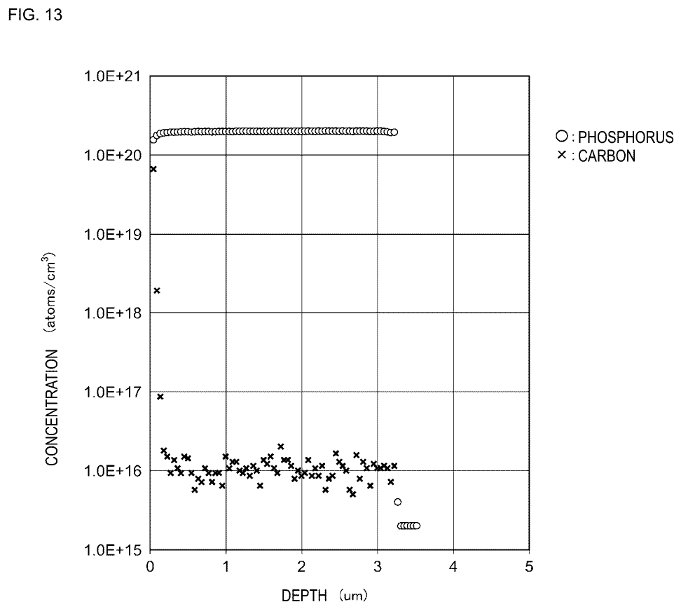

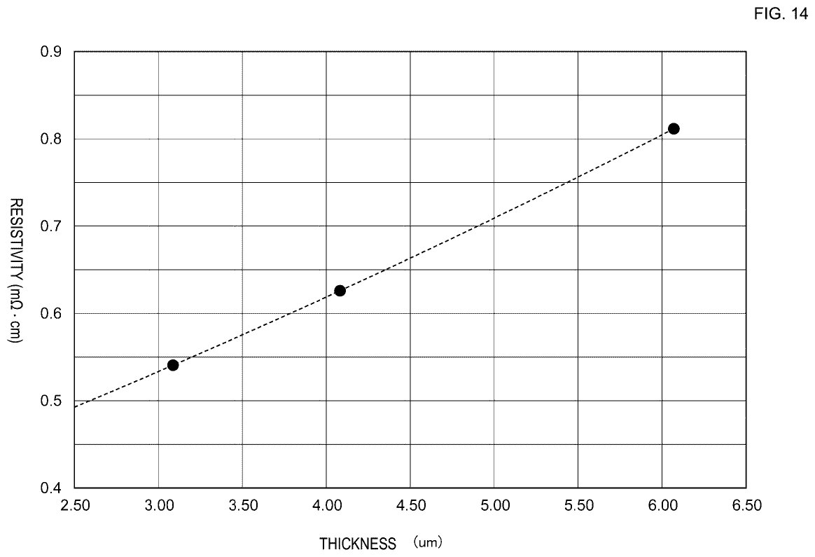

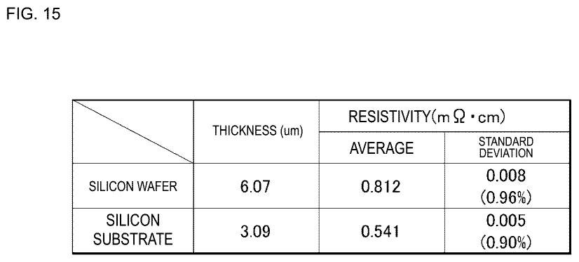

Next, physical properties of the silicon substrate of the resonator according to the first embodiment of the present disclosure will be described with reference to FIGS. 13 to 15. FIG. 13 is a graph showing the concentrations of phosphorus (P) and carbon (C) in the silicon substrate 270 in the first embodiment. FIG. 14 is a graph showing the resistivity of the silicon substrate 270 in the first embodiment and the silicon wafer 250 shown in FIG. 6. FIG. 15 is a table for comparing the silicon substrate 270 in the first embodiment with the silicon wafer 250 shown in FIG. 6. In FIG. 13, a horizontal axis is a depth from the front surface of the silicon substrate 270, and a vertical axis is the concentration in the silicon substrate 270. In FIG. 14, the horizontal axis is the thickness of the silicon active layer 263 in the silicon substrate 270 and the thickness of the silicon wafer 250, and the vertical axis is the resistivity of the silicon substrate 270 and the silicon wafer 250. In FIGS. 13 to 15, the thickness of the silicon active layer 263 in the silicon substrate 270 is 3.09 μm. In addition, in FIGS. 14 and 15, the thickness of the silicon wafer 250 is 6.07 μm.

As shown in FIG. 13, in the silicon substrate 270, the concentration of phosphorus (P) is 1.1×10²⁰ [atoms/cm³] or higher over the thickness of the silicon active layer 263. In this manner, the concentration of the phosphorus (P) can be raised, and the resistivity of the vibration portion 120 can be lowered, compared to the silicon substrate in the related art in which the concentration of the phosphorus (P) is approximately 1.0×10²⁰ [atoms/cm³].

More preferably, in the silicon substrate 270, the concentration of the phosphorus (P) is 2.0×10²⁰ [atoms/cm³] or higher and 4.0×10²⁰ [atoms/cm³] or lower over the thickness of the silicon active layer 263. An upper limit value of the concentration of phosphorus (P) in the silicon substrate 270 is a solid solubility limit of the phosphorus (P) with respect to the silicon (Si).

In addition, in the silicon substrate 270, the concentration of the carbon (C) is 1.1×10¹⁸ [atoms/cm³] or lower over the thickness of the silicon active layer 263.

Here, in general, the phosphorus (P) has a property that the phosphorus (P) is easily coupled to a contaminant such as the carbon (C) present on the front surface of the wafer. The carbon (C) inactivates the phosphorus (P) when coupled to the phosphorus (P). Therefore, the carbon (C) can be a factor that hinders a decrease in the resistivity.

Meanwhile, in the silicon substrate 270, the concentration of the carbon (C) is set to be 1.1×10¹⁸ [atoms/cm³] or lower. In this manner, inactivation of the phosphorus (P) can be suppressed. Therefore, the resistivity of the vibration portion 120 can be lowered, compared to the related art, and frequency temperature characteristics of the resonant frequency can be improved.

In other words, the concentration of the phosphorus (P) in the silicon substrate 270 is equal to or more than 110 times the concentration of the carbon (C). In this manner, the concentration of the phosphorus (P) can be raised, compared to the silicon substrate in the related art, the resistivity of the vibration portion 120 can be lowered, and the inactivation of the phosphorus (P) can be suppressed. Therefore, the resistivity of the vibration portion 120 can be lowered, compared to the related art, and frequency temperature characteristics of the resonant frequency can be improved.

In addition, as is apparent from FIG. 13, in the silicon substrate 270, the phosphorus (P) is diffused through the heat treatment. In this manner, the concentration of the phosphorus (P) is uniform or substantially uniform over the thickness of the silicon active layer 263. In this way, the SOI wafer 260 is heated to diffuse the phosphorus (P). In this manner, it is possible to suppress segregation of the phosphorus (P) on the front surface or in the vicinity of the front surface of the silicon active layer 263 in the silicon substrate 270.

As shown in FIG. 14, in the silicon wafer 250 in an initial state before Step S302 to Step S305 are performed, the resistivity is 0.812 [mΩ·cm] on average. Meanwhile, the silicon substrate 270 formed by repeating Step S302 to Step S305 has an average resistivity of 0.541 [mΩ·cm]. In this way, since the silicon substrate 270 has a resistivity of 0.60 [mΩ·cm] or lower, the resistivity of the vibration portion 120 can be lowered, compared to the related art, and the frequency temperature characteristics of the resonant frequency can be improved.

More preferably, the silicon substrate 270 has a resistivity of 0.40 [mΩ·cm] or higher and 0.55 [mΩ·cm] or lower.

In addition, as shown in FIG. 15, in the silicon wafer 250, a standard deviation of the resistivity which indicates variations in the resistivity is 0.008. Meanwhile, in the silicon substrate 270, the standard deviation of the resistivity is 0.005, and is substantially the same as that of the silicon wafer 250. In this way, the variations in the resistivity do not change or hardly change before and after Step S302 to Step S305.

Furthermore, the silicon substrate 270 has a surface roughness of 0.3 nm or smaller, specifically, approximately 0.25 nm. The surface roughness through Step S302 to Step S305 does not occur, or is less likely to occur.

### Second Embodiment

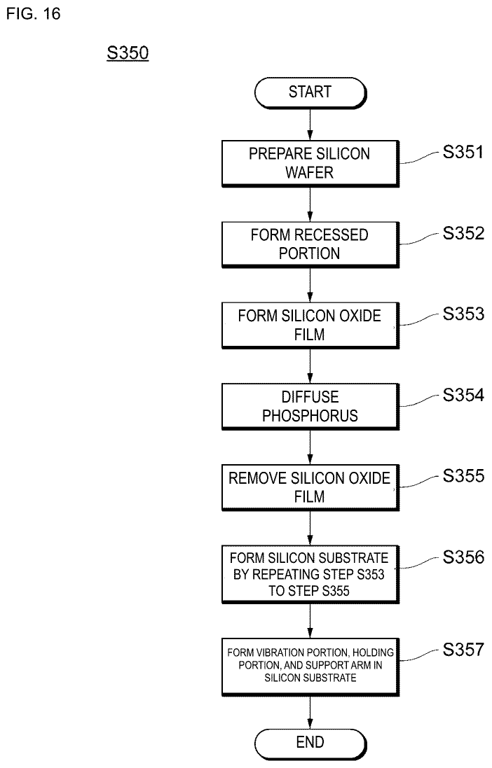

Next, the resonator and a method for manufacturing the resonator according to a second embodiment of the present disclosure will be described with reference to FIGS. 16 to 20. In addition, the same or similar components as those in the first embodiment are denoted by the same or similar reference numerals. Hereinafter, points different from those in the first embodiment will be described. In addition, the same operational effects according to the same configuration will not be sequentially described. Furthermore, since the resonator in the second embodiment is substantially the same as the resonator 10 in the first embodiment, the illustration and description thereof will be omitted.

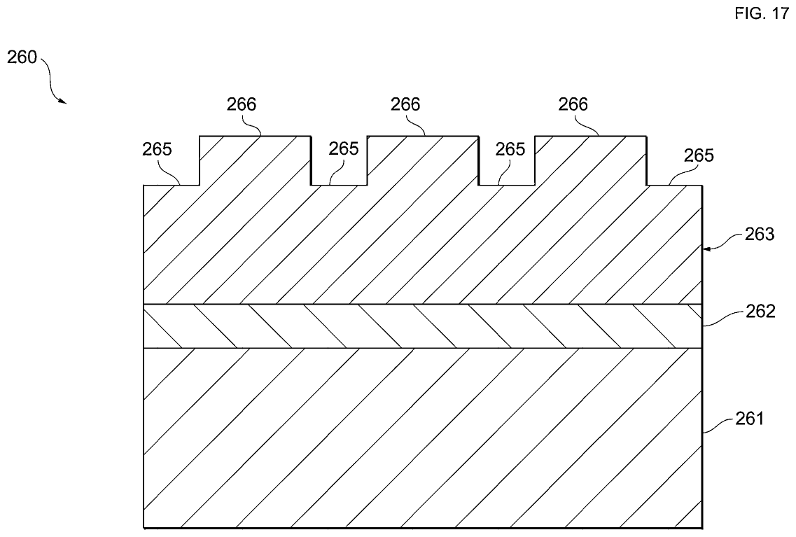

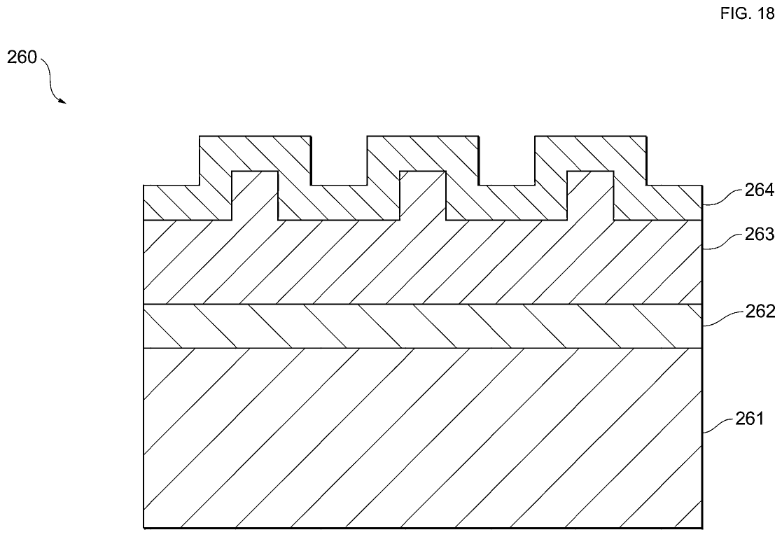

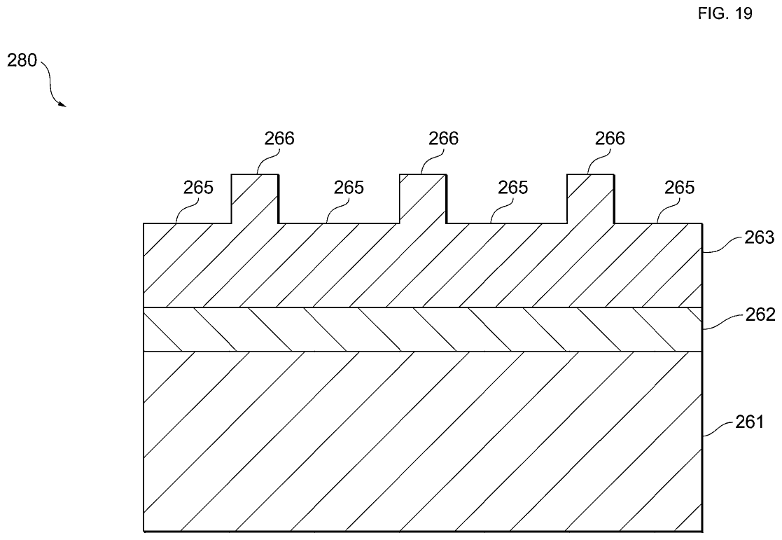

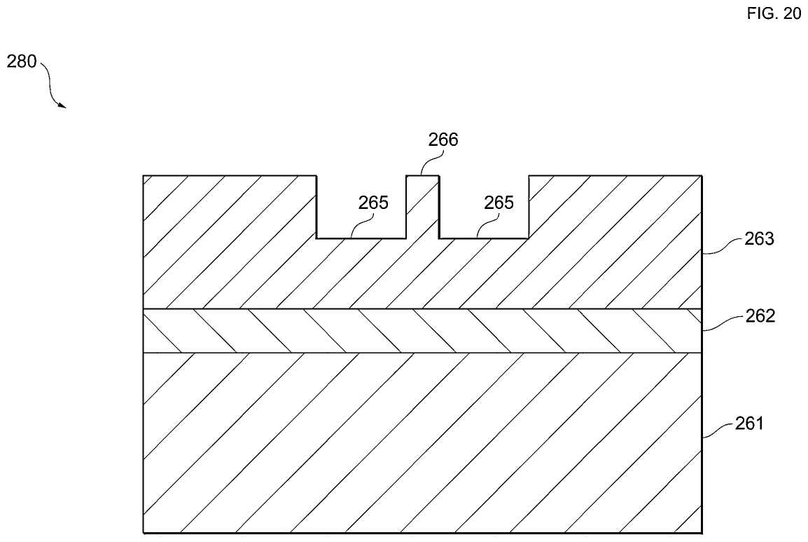

First, a method for manufacturing the resonator according to the second embodiment of the present disclosure will be described with reference to FIG. 16. FIG. 16 is a flowchart showing a method for manufacturing the resonator in the second embodiment. FIG. 17 is a cross-sectional view for describing Step S352 shown in FIG. 16. FIG. 18 is a cross-sectional view for describing Step S353 shown in FIG. 16. FIG. 19 is a cross-sectional view for describing an example in Step S356 shown in FIG. 16. FIG. 20 is a cross-sectional view for describing another example in Step S356 shown in FIG. 16.

Since Step S351 shown in FIG. 16 is the same as Step S301 according to the first embodiment, the description thereof will be omitted. Hereinafter, an example of preparing the SOI wafer 260 will be described as in the first embodiment.

Next, the SOI wafer 260 is processed to form a recessed portion 265 (S352). Specifically, as shown in FIG. 17, a portion of the front surface of the silicon active layer 263 is removed through etching to form one or more recessed portions 265. As a result, on the front surface of the silicon active layer 263, a portion which is not removed, that is, a portion between the recessed portions 265 and the recessed portions 265 is a protruding portion 266.

In addition, Step S352 is not limited to a case of being performed between Step S351 and Step S352. For example, the recessed portion 265 may be formed as a portion in Step S351, or may be formed as a pretreatment for the thermal oxidation in Step S353.

Returning to FIG. 16, next, the SOI wafer 260 is heated in an oxygen atmosphere to form the silicon oxide film (SiO₂ film) 264 (S353).

More specifically, as in the first embodiment, in the SOI wafer 260, the front surface of the silicon active layer 263 is oxidized through the thermal oxidation performed by heating in an oxygen atmosphere, and is changed to the silicon oxide film (SiO₂ film) 264.

Here, as shown in FIG. 18, a portion of the recessed portion 265 and the protruding portion 266 which are formed in Step S352 is also changed to the silicon oxide film (SiO₂ film) 264 through the thermal oxidation. Since the recessed portion 265 is included on the front surface of the silicon active layer 263, a surface area of the silicon active layer 263 is increased. Therefore, it is possible to increase a volume of the silicon oxide film (SiO₂ film) 264 formed through the thermal oxidation.

Since Step S354 and Step S355 which are shown in FIG. 16 each are the same as Step S303 and Step S304 in the first embodiment, the description thereof will be omitted.

Returning to FIG. 16, next, Step S353 to Step S355 are repeated for the SOI wafer 260 to form the silicon substrate 280 (S356). As shown in FIG. 19, the silicon substrate 280 to be formed includes the support layer 261, the insulation layer 262, and the silicon active layer 263, as in the silicon substrate 270 of the first embodiment. The silicon substrate 280 is different from the silicon substrate 270 in that the recessed portion 265 and the protruding portion 266 are formed in the silicon active layer 263. In this way, since the silicon substrate 280 includes the recessed portion 265 formed in the silicon active layer 263, a surface area of the silicon active layer 263 is increased. Therefore, it is possible to increase a volume of the silicon oxide film (SiO₂ film) 264 formed through the thermal oxidation. Therefore, the silicon (Si) of the silicon active layer 263 can be more efficiently consumed as the silicon dioxide (SiO₂), and the resistivity of the silicon substrate 280 can be more easily lowered.

In Step S356, Step S353 to Step S355 may be repeated to form the silicon substrate 280 having the narrowed protruding portion 266. As shown in FIG. 20, the width of the protruding portion 266 in the silicon active layer 263 is narrower than that of the protruding portion 266 shown in FIG. 19. The narrowed protruding portion 266 can be formed by adjusting a heating time of the heat treatment when the phosphorus (P) is diffused in Step S354. In addition, since a diffusion type of the phosphorus (P) is changed by adjusting the heating time, the resistivity of the narrowed protruding portion 266 is different from that of other portions of the silicon active layer 263. Specifically, the resistivity of the protruding portion 266 is lower than the resistivity of other portions. In this manner, the silicon substrate 280 can have a plurality of regions having different resistivity, and the resonator having a plurality of frequency temperature characteristics can be realized.

Since Step S357 shown in FIG. 16 is the same as Step S306 according to the first embodiment, the description thereof will be omitted.

Hitherto, the exemplary embodiments of the present disclosure have been described. The resonator according to one embodiment of the present disclosure includes the vibration portion configured to vibrate in a predetermined vibration mode as a main vibration, and includes the vibration portion formed on the silicon substrate containing the phosphorus (P). In the silicon substrate, the concentration of the phosphorus (P) is 1.1×10²⁰ [atoms/cm³] or higher. In this manner, the concentration of the phosphorus (P) can be raised, and the resistivity of the vibration portion can be lowered, compared to the silicon substrate in the related art in which the concentration of the phosphorus (P) is approximately 1.0×10²⁰ [atoms/cm³]. In addition, in the silicon substrate, the concentration of the carbon (C) is 1.1×10¹⁸ [atoms/cm³] or lower. In this manner, the inactivation of the phosphorus (P) can be suppressed. Therefore, the resistivity of the vibration portion can be lowered, compared to the related art, and the frequency temperature characteristics of the resonant frequency can be improved.

In addition, the resonator according to one embodiment of the present disclosure includes the vibration portion configured to vibrate in a predetermined vibration mode as a main vibration, the vibration portion being formed on the silicon substrate containing the phosphorus (P). In the silicon substrate, the concentration of the phosphorus (P) is equal to or more than 110 times the concentration of the carbon (C). In this manner, the concentration of the phosphorus (P) can be raised, compared to the silicon substrate in the related art, the resistivity of the vibration portion 120 can be lowered, and the inactivation of the phosphorus (P) can be suppressed. Therefore, the resistivity of the vibration portion can be lowered, compared to the related art, and the frequency temperature characteristics of the resonant frequency can be improved.

In addition, the resonator according to an embodiment of the present disclosure includes the vibration portion configured to vibrate in a predetermined vibration mode as a main vibration, the vibration portion being formed on the silicon substrate containing the phosphorus (P). The resistivity of the silicon substrate is 0.60 [mΩ·cm] or lower. In this manner, the resistivity of the vibration portion can be lowered, compared to the related art, and the frequency temperature characteristics of the resonant frequency can be improved.

In addition, in the above-described resonator, the silicon substrate is formed of the SOI wafer including the support layer, the insulation layer, and the silicon active layer to which the phosphorus (P) is added. Here, since the silicon active layer can be formed to be thinner, the concentration of phosphorus (P) in the SOI wafer can be easily raised.

In addition, in the above-mentioned resonator, the silicon substrate includes the recessed portion formed in the silicon active layer. In this manner, since a surface area of the silicon active layer is increased, it is possible to increase a volume of the silicon oxide film (SiO₂ film) formed through the thermal oxidation. Therefore, the silicon (Si) of the silicon active layer can be more efficiently consumed as the silicon dioxide (SiO₂), and the resistivity of the silicon substrate can be more easily lowered.

The resonance device according to an embodiment of the present disclosure includes the lid body and the above-described resonator.

In this manner, the resonance device that further lowers the resistivity of the vibration portion can be easily realized.

The method for manufacturing the resonator according to one embodiment of the present disclosure includes a step of preparing the silicon wafer to which the phosphorus (P) is added, a step of heating the silicon wafer in the oxygen atmosphere to form the silicon oxide film (SiO₂ film), a step of removing the silicon oxide film (SiO₂ film) from the silicon wafer, a step of forming the silicon substrate by performing the step of forming the silicon oxide film and the step of removing the silicon oxide film once or more times, and a step of forming the vibration portion configured to vibrate in a predetermined vibration mode as a main vibration, on the silicon substrate. In this manner, the concentration of the phosphorus (P) can be raised, compared to a method for manufacturing the resonator in the related art, and the resistivity of the vibration portion can be lowered. The phosphorus (P) can be added in advance, and becomes less likely to be coupled to a contaminant such as the carbon (C). Therefore, the inactivation of the phosphorus (P) can be suppressed. Therefore, the resistivity of the vibration portion can be lowered, compared to the related art, and the frequency temperature characteristics of the resonant frequency can be improved.

In addition, the above-described method for manufacturing the resonator further includes a step of heating the silicon wafer to diffuse the phosphorus (P) between the step of forming the silicon oxide film (SiO₂ film) and the step of removing the silicon oxide film (SiO₂ film). In this manner, it is possible to suppress the segregation of the phosphorus (P) on the front surface or in the vicinity of the front surface of the silicon substrate.

Each of the embodiments described above is provided to facilitate understanding of the present disclosure, and is not intended to be interpreted as limiting the present disclosure. The present disclosure may be modified/improved without departing from the concept of the present disclosure, and the present disclosure also includes equivalents thereof. That is, those in which design changes are added as appropriate to each embodiment by the person skilled in the art are included in the scope of the present disclosure as long as characteristics of the present disclosure are included. For example, each element provided in the embodiments, the disposition thereof, the material, the condition, the shape, the size, and the like are not limited to those illustrated, and can be changed as appropriate. In addition, each of the embodiments is an example, and configurations described in different embodiments can be partially replaced or combined, and these are also included in the scope of the present disclosure as long as the characteristics of the present disclosure are included.

### REFERENCE SIGNS LIST

1 resonance device
10 resonator
20 lower lid
21 recessed portion
22 bottom plate
23 side wall
30 upper lid
31 recessed portion
32 bottom plate
33 side wall
34 getter layer
50 MEMS substrate
60 joint portion
61 aluminum layer
62 germanium layer
70 connection wire
76A contact electrode
76B contact electrode
110 support arm
120 vibration portion
130 base portion
135, 135A, 135B, 135C, 135D vibration arm
140 holding portion
235 protection film
236 frequency adjustment film
240 parasitic capacitance reduction film
250 silicon wafer
260 SOI wafer
261 support layer
262 insulation layer
263 silicon active layer
264 silicon oxide film
265 recessed portion
266 protruding portion
270 silicon substrate
280 silicon substrate
E1 metal layer
E2 metal layer
F2 Si substrate
F3 piezoelectric thin film
F21 silicon oxide layer
G weight portion
L1 Si wafer
L3 Si substrate
L31 silicon oxide film
P virtual plane
T4 terminal
V1 via
V2 via
V3 through electrode

1. A resonator comprising:
a silicon substrate containing phosphorus; and
a vibration portion on the silicon substrate and constructed to vibrate in a predetermined vibration mode as a main vibration,
wherein in the silicon substrate, a concentration of the phosphorus is 1.1×10²⁰ [atoms/cm³] or higher, and a concentration of carbon is 1.1×10¹⁸ [atoms/cm³] or lower.

2. The resonator according to claim 1, wherein in the silicon substrate, the concentration of the phosphorus is 2.0×10²⁰ [atoms/cm³] or higher and 4.0×10²⁰ [atoms/cm³] or lower.

3. The resonator according to claim 1, wherein the silicon substrate comprises an SOI wafer including a support layer, an insulation layer, and a silicon active layer containing the phosphorus.

4. The resonator according to claim 3, wherein the silicon substrate includes a recessed portion in the silicon active layer.

5. A resonance device comprising:
a lid body; and
the resonator according to claim 1.

6. A resonator comprising:
a silicon substrate containing phosphorus; and
a vibration portion on the silicon substrate and constructed to vibrate in a predetermined vibration mode as a main vibration,
wherein in the silicon substrate, a concentration of the phosphorus is equal to or more than 110 times a concentration of carbon.

7. The resonator according to claim 6, wherein the silicon substrate comprises an SOI wafer including a support layer, an insulation layer, and a silicon active layer containing the phosphorus.

8. The resonator according to claim 7, wherein the silicon substrate includes a recessed portion in the silicon active layer.

9. A resonance device comprising:
a lid body; and
the resonator according to claim 6.

10. A resonator comprising:
a silicon substrate containing phosphorus; and
a vibration portion on the silicon substrate and constructed to vibrate in a predetermined vibration mode as a main vibration,
wherein a resistivity of the silicon substrate is 0.60 [mΩ·cm] or lower.

11. The resonator according to claim 10, wherein the resistivity of the silicon substrate is 0.40 [mΩ·cm] or higher and 0.55 [mΩ·cm] or lower.

12. The resonator according to claim 10, wherein the silicon substrate comprises an SOI wafer including a support layer, an insulation layer, and a silicon active layer containing the phosphorus.

13. The resonator according to claim 12, wherein the silicon substrate includes a recessed portion in the silicon active layer.

14. A resonance device comprising:
a lid body; and
the resonator according to claim 10.

15. A method for manufacturing a resonator, the method comprising:
adding phosphorous to a silicon wafer;
heating the silicon wafer in an oxygen atmosphere to form a silicon oxide film on the silicon wafer;
removing the silicon oxide film from the silicon wafer;
forming a silicon substrate by performing the forming of the silicon oxide film and the removing of the silicon oxide film once or more times; and
forming a vibration portion that vibrates in a predetermined vibration mode as a main vibration, on the silicon substrate.

16. The method for manufacturing a resonator according to claim 15, further comprising:
heating the silicon wafer to diffuse the phosphorus between the forming of the silicon oxide film and the removing of the silicon oxide film.

17. The method for manufacturing a resonator according to claim 15, wherein the forming of the silicon substrate by the performing of the forming of the silicon oxide film and the removing of the silicon oxide film is repeated until the silicon substrate has a concentration of the phosphorus of 1.1×10²⁰ [atoms/cm³] or higher, and a concentration of carbon of 1.1×10¹⁸ [atoms/cm³] or lower.

18. The method for manufacturing a resonator according to claim 15, wherein the forming of the silicon substrate by the performing of the forming of the silicon oxide film and the removing of the silicon oxide film is repeated until the silicon substrate has a concentration of the phosphorus equal to or more than 110 times a concentration of carbon.

19. The method for manufacturing a resonator according to claim 15, wherein the forming of the silicon substrate by the performing of the forming of the silicon oxide film and the removing of the silicon oxide film is repeated until the silicon substrate has a resistivity of is 0.60 [mΩ·cm] or lower.
